(19) United States
(12) Patent Application Publication
(10) Pub. No.: US 2023/0197157 A1
(43) Pub. Date: Jun. 22, 2023

(54) ADAPTIVE READ-RETRY OFFSET BASED ON WORD LINE GROUPS FOR SYSTEMS

(71) Applicant: Micron Technology, Inc., Boise, ID (US)

(72) Inventors: Sandeep Kadasani, Boise, ID (US); Pitamber Shukla, Boise, ID (US); Scott A. Stoller, Boise, ID (US); Renato Padilla, Boise, ID (US); Chi Ming Chu, Boise, ID (US)

(21) Appl. No.: 17/741,189

(22) Filed: May 10, 2022

Related U.S. Application Data
(60) Provisional application No. 63/291,218, filed on Dec. 17, 2021.

(51) Int. Cl. G11C 16/08; G11C 16/34; G11C 16/30

(52) U.S. Cl. CPC G11C 16/08; G11C 16/30; G11C 16/3495

(57) ABSTRACT

A method includes determining, for a set of memory cells of a word line group, a parameter corresponding to a quality of the set of memory cells of the word line group and determining, for the set of memory cells, a range of voltage offset values corresponding to the parameter. The method can further include determining a voltage offset to be applied to the set of memory cells of the word line group based on the parameter or the range of voltage offset values, or both and applying a signal corresponding to the determined voltage offset to the set of memory cells of the word line group.

### TECHNICAL FIELD

Embodiments of the disclosure relate generally to memory sub-systems, and more specifically, relate to application of an adaptive read-retry offset based on word line groups for systems.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1 illustrates an example computing system that includes a memory sub-system in accordance with some embodiments of the present disclosure.

FIG. 2 illustrates an example of a memory device coupled to a voltage offset component in accordance with some embodiments of the present disclosure.

FIG. 3 illustrates another example of a memory device coupled to a voltage offset component in accordance with some embodiments of the present disclosure.

FIG. 4 illustrates an example flow diagram corresponding to application of an adaptive read-retry offset based on word line groups for systems in accordance with some embodiments of the present disclosure.

FIG. 5 is a flow diagram corresponding to a method for and adaptive read-retry offset based on word line groups for systems in accordance with some embodiments of the present disclosure.

FIG. 6 is a block diagram of an example computer system in which embodiments of the present disclosure may operate.

### DETAILED DESCRIPTION

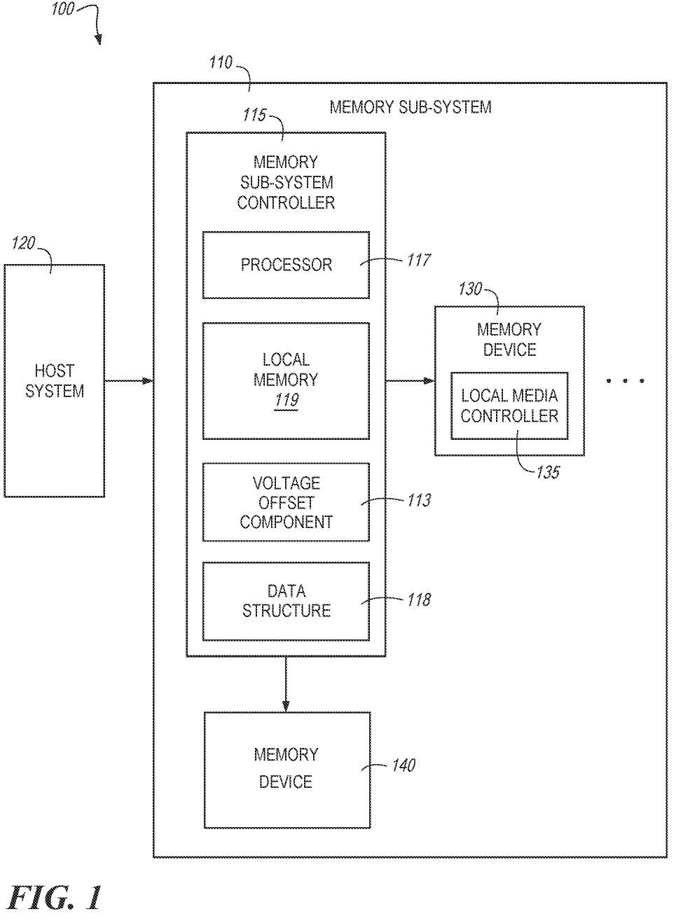

Aspects of the present disclosure are directed to an adaptive read-retry offset based on word line groups in a memory sub-system, in particular to memory sub-systems that include circuitry to control application of a voltage offset to a word line group. A memory sub-system can be a storage system, storage device, a memory module, or a combination of such. An example of a memory sub-system is a storage system such as a solid-state drive (SSD). Examples of storage devices and memory modules are described below in conjunction with FIG. 1, et alibi. In general, a host system can utilize a memory sub-system that includes one or more components, such as memory devices that store data. The host system can provide data to be stored at the memory sub-system and can request data to be retrieved from the memory sub-system.

A memory device can be a non-volatile memory device. One example of non-volatile memory devices is a NOT-AND(NAND) memory device (also known as flash technology). Other examples of non-volatile memory devices are described below in conjunction with FIG. 1. A non-volatile memory device is a package of one or more dice. Each die can consist of one or more planes. Planes can be groups into logic units (LUN). For some types of non-volatile memory devices (e.g., NAND devices), each plane consists of a set of physical blocks. Each block consists of a set of pages. Each page consists of a set of memory cells (“cells”). A cell is an electronic circuit that stores information. A block hereinafter refers to a unit of the memory device used to store data and can include a group of memory cells, a word line group, a word line, or individual memory cells. For some memory devices, blocks (also hereinafter referred to as “memory blocks”) are the smallest area than can be erased. Pages cannot be erased individually, and only whole blocks can be erased.

Each of the memory devices can include one or more arrays of memory cells. Depending on the cell type, a cell can store one or more bits of binary information, and has various logic states that correlate to the number of bits being stored. The logic states can be represented by binary values, such as “0” and “1”, or combinations of such values. There are various types of cells, such as single level cells (SLCs), multi-level cells (MLCs), triple level cells (TLCs), and quad-level cells (QLCs). For example, a SLC can store one bit of information and has two logic states.

Some NAND memory devices employ a floating-gate architecture in which memory accesses are controlled based on a relative voltage change between the bit line and the word lines. Other examples of NAND memory devices can employ a replacement-gate architecture that can include the use of word line layouts that can allow for charges corresponding to data values to be trapped within memory cells based on properties of the materials used to construct the word lines. While both floating-gate architectures and replacement-gate architectures employ the use of select gates (e.g., select gate transistors), replacement-gate architectures can include multiple select gates coupled to a string of NAND memory cells. Further, replacement-gate architectures can include programmable select gates.

The pages of memory cells of, for example, a NAND memory device can be arranged in a row and have a bit line structure that connects into a memory “address” called a word line. The address provides a means of identifying a location for data storage, and the word line forms an electrical path allowing all the memory cells on that row to be activated at the same time for storage (“write”) or retrieval (“read”). A set of memory cells (e.g., a page of memory cells or multiple pages of memory cells) that are coupled to a particular word line or to a set of particular word lines can be referred to herein as a “word line group” or a “page of memory cells of a word line group.” In the alternative, a word line group can be described as comprising or including one or more pages or sets of memory cells.

Due to the characteristics of memory cells, and, more specifically, the inherent characteristics of non-volatile memory cells (e.g., NAND memory cells), a quality of such memory cells generally degrade over time. This degradation in quality can be based on a quantity of program-erase cycles (PECs) experienced by the memory cells, a frequency that data is written to or read from the memory cells, an amount of time that data written to the memory cells is stored by the memory cells, workloads experienced by the memory cells, operational temperatures of the memory cells, and/or process variations within the memory cells (or sets of the memory cells), among other factors that can contribute to degradation of such memory cells. This degradation of quality of the memory cells can give rise to errors involving data written to the memory cells, which can be costly to correct in terms of time, power consumption, and/or quality of service (QoS).

For example, the degradation of the quality of the memory cells and/or memory dice, chips, components, etc. of memory devices of a memory sub-system can lead to scenarios in which a threshold voltage (V_{T}) distribution of the memory cells and/or word line groups of a memory device can shift or “drift” over time based on the quality of the memory cells, word line groups, memory dice, etc. of the memory sub-system. That is, the V_{T} distribution of the memory cells and/or word line groups, etc. can change over time such that the actual V_{T} distribution corresponding to the memory cells and/or word line groups, etc. is different than the expected V_{T} distribution corresponding to the memory cells and/or word line groups, etc., which can lead to the introduction of errors in data that is written to and/or stored by memory cells accessible by word line groups of the memory device.

When such errors occur, the raw bit error rate (RBER) of the memory device increases, which can, in turn, affect a trigger rate associated with of the memory device. The trigger rate can be used to benchmark the read performance of a memory device and can be directly related to the read time and/or the read latency associated with memory cells of the memory device and, accordingly, can have a large effect on the latency and/or QoS of the memory device.

Some approaches attempt to mitigate the adverse effects of shifts in the V_{T} distribution of the memory cells and/or word line groups by intermittently or periodically applying an offset voltage signal (e.g., a read recovery voltage signal) to all of the memory cells and/or all of the word line groups of a memory device in an attempt to correct such shifts in the V_{T} distribution of the memory cells and/or word line groups. Although such approaches can be effective in alleviating the adverse effects of “worst case scenarios” of shifts in the V_{T} distribution of the memory cells and/or word line groups, and, hence “worst case scenarios” of RBER and/or trigger rates, reliance on application of a particular offset voltage signal (e.g., a signal having a particular voltage associated therewith) to each word line group and, therefore, to each set or page of memory cells to attempt to correct such shifts in the V_{T} distribution of the memory cells and/or word line groups can increase latency, thereby reducing QoS for the memory sub-system as a whole. Further, such approaches fail to account for program-erase counts (PECs) experienced by memory cells (e.g., pages, word line groups, etc.) when determining a particular offset voltage signal to apply.

Aspects of the present disclosure address the above and other deficiencies by allowing for application of a voltage offset signal to a word line group and, more specifically, to at least one word line group of a memory device independent of application of different voltage offset signals to other word line groups of the memory device. Accordingly, aspects of the present disclosure can allow for voltage offset signals having different voltages, periodicities, magnitudes, and/or frequencies of application to be applied to different word line groups of the memory device independently.

As described in more detail herein, application of the voltage offset signals (e.g., one or more read retry (RR) offset signals) can be based on a determined quality of memory cells of various word line groups and/or a quality of the word line groups. Such “quality characteristics” of the memory cells and/or word line groups can be based on PECs experienced by the word line groups, a frequency that data is written to or read from the word line groups, an amount of time that data written to the word line groups is stored by the memory cells associated with particular word line groups, workloads experienced by the word line groups, operational temperatures of the memory cells, and/or process variations within the memory cells (or word line groups), among other factors described herein, which can give rise to shifts in the V_{T} distribution of the memory cells of the word line groups and/or the word line groups themselves.

In some embodiments, the voltage offset signals described herein can be based on other quality characteristics, such as read disturb metrics and/or “cross-temperature” metrics. In general, read disturb metrics refer to quality characteristics of memory cells and, hence, word line groups of such memory cells that experience voltage fluctuations as a result of memory access operations, such as read operations. “Cross-temperature” metrics refer to quality characteristics of memory cells that may arise during operation of a memory sub-system that can receive various memory access requests (e.g., requests to read or “retrieve” data and/or requests to write or “program” data to a memory device of the memory sub-system). Due to behaviors of the memory sub-system, the data can be written to the memory device when the memory device is operating at a first temperature and can be read from the memory device when the memory device is operating at a second temperature. This phenomenon (e.g., the sensing of data at a temperature different from that observed during programming) can be referred to as the “cross-temperature” phenomenon and can be a source of a large number of failed bits detected in performance of a read operation, which can lead to unrecoverable data corruption even using well-known error correction codes. Accordingly, a metric by which the performance of a memory device can be measured is the cross-temperature behavior of the memory device - that is, by how accurate the data read from the memory is when the data is read at a different temperature than a temperature at which the data was written to the memory device.

In addition, embodiments provide that information corresponding to maximum and minimum offset values can be written to a table (e.g., a lookup table stored by memory associated with a memory sub-system) to facilitate performance of the operations described herein. In some embodiments, such table(s) can be compressed in firmware associated with the memory sub-system and/or memory device to store only the maximum positive and negative offsets associated with the quality characteristics to preserve the amount of memory space required to store such information. Further, embodiments herein provide that the quality characteristics stored in such table(s) can include different maximum and/or minimum values based on a quantity of PECs experienced by the individual word line groups of the memory device, among other quality characteristics.

By allowing for the application of voltage offset signals of varying or different voltages to individual word line groups of the memory device, the overall performance of the memory device can be improved in comparison to approaches that apply voltage offset signals having the same voltage to all of the word line groups. In addition, by allowing for the application of voltage offset signals of varying or different voltages to individual word line groups of the memory device, as described herein, RBER for the memory device and trigger rates for the memory device can be improved in comparison to approaches that apply voltage offset signals having the same voltage to all of the word line groups. For example, by dynamically altering the voltage offset signals for individual word line groups of the memory device, the voltage offset can be made finer for each of the word line groups, thereby improving the reliability of the memory device and enhancing the QoS of the memory device.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, server, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, and the like.

The host system 120 can include a processor chipset and a software stack executed by the processor chipset. The processor chipset can include one or more cores, one or more caches, a memory controller (e.g., an SSD controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), Small Computer System Interface (SCSI), a double data rate (DDR) memory bus, a dual in-line memory module (DIMM) interface (e.g., DIMM socket interface that supports Double Data Rate (DDR)), Open NAND Flash Interface (ONFI), Double Data Rate (DDR), Low Power Double Data Rate (LPDDR), or any other interface. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the PCIe interface. The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random-access memory (DRAM) and synchronous dynamic random access memory (SDRAM).

Some examples of non-volatile memory devices (e.g., memory device 130) include NOT-AND(NAND) type flash memory and write-in-place memory, such as three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130, 140 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLC) can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as three-dimensional cross-point arrays of non-volatile memory cells and NAND type memory (e.g., 2D NAND, 3D NAND) are described, the memory device 130 can be based on any other type of non-volatile memory or storage device, such as such as, read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

The memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device 130 and/or the memory device 140. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address, physical media locations, etc.) that are associated with the memory devices 130. The memory sub-system controller 115 can further include host interface circuitry to communicate with the host system 120 via the physical host interface. The host interface circuitry can convert the commands received from the host system into command instructions to access the memory device 130 and/or the memory device 140 as well as convert responses associated with the memory device 130 and/or the memory device 140 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory device 130 and/or the memory device 140.

In some embodiments, the memory device 130 includes local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device combined with a local controller (e.g., local controller 135) for media management within the same memory device package. An example of a managed memory device is a managed NAND (MNAND) device.

As shown in FIG. 1, the memory sub-system 110 can include a data structure 118. As used herein, a “data structure” refers to a specialized format for organizing and/or storing data, which may or may not be organized in rows and columns. Examples of data structures include arrays, files, records, tables, trees, linked lists, hash tables, etc. In some embodiments, the data structure 118 can be configured to store one or more look-up tables that contain predetermined voltage offset ranges that are based on different word line groups of the memory sub-system 110. In some embodiments, the data structure 118 can be accessed during performance of operations related to application of a voltage offset to a word line group to determine a range of voltage offsets that may be applied to a particular word line group of the memory sub-system 110.

The memory sub-system 110 can include a voltage offset component 113. Although not shown in FIG. 1, so as to not obfuscate the drawings, the voltage offset component 113 can include various circuitry to facilitate performance of operations related to application of a voltage offset to a word line group. As described in more detail, herein, the operations related to application of a voltage offset to a word line group can be performed using individual word line groups (or combinations of word line groups) based on quality characteristics of the word line groups and/or memory cells of the word line groups. By selectively controlling performance of operations related to application of a voltage offset to a word line group based on parameters corresponding to the quality of the memory cells (e.g., a quantity of program-erase counts (PECs) experienced by the memory cells), latency of the memory sub-system 110 can be reduced in comparison to approaches that perform voltage offset operations on all of the word line groups of the memory sub-system 110 regardless of the quality characteristics of the word line groups and/or memory cells of the word line groups, thereby improving QoS for the memory sub-system 110. In some embodiments, the voltage offset component 113 can include special purpose circuitry in the form of an ASIC, FPGA, state machine, and/or other logic circuitry that can allow the voltage offset component 113 to orchestrate and/or perform operations described herein involving the memory device 130 and/or the memory device 140.

In some embodiments, the memory sub-system controller 115 includes at least a portion of the voltage offset component 113. For example, the memory sub-system controller 115 can include a processor 117 (processing device) configured to execute instructions stored in local memory 119 for performing the operations described herein. In some embodiments, the voltage offset component 113 is part of the host system 110, an application, or an operating system.

In some embodiments, the memory sub-system 110, and hence the voltage offset component 113, the processor 119, and the memory devices 130/140, can be resident on a mobile computing device such as a smartphone, laptop, or phablet among other similar computing devices. As used herein, the term “mobile computing device” generally refers to a handheld computing device that has a slate or phablet form factor. In general, a slate form factor can include a display screen that is between approximately 3 inches and 5.2 inches (measured diagonally), while a phablet form factor can include a display screen that is between approximately 5.2 inches and 7 inches (measured diagonally). Examples of “mobile computing devices” are not so limited, however, and in some embodiments, a “mobile computing device” can refer to an IoT device or any other type of edge computing device(s).

Further, the voltage offset component 113 can be resident on the memory sub-system 110. As used herein, the term “resident on” refers to something that is physically located on a particular component. For example, the voltage offset component 113 being “resident on” the memory sub-system 110 refers to a condition in which the hardware circuitry that comprises the voltage offset component 113 is physically located on the memory sub-system 110. The term “resident on” can be used interchangeably with other terms such as “deployed on” or “located on,” herein.

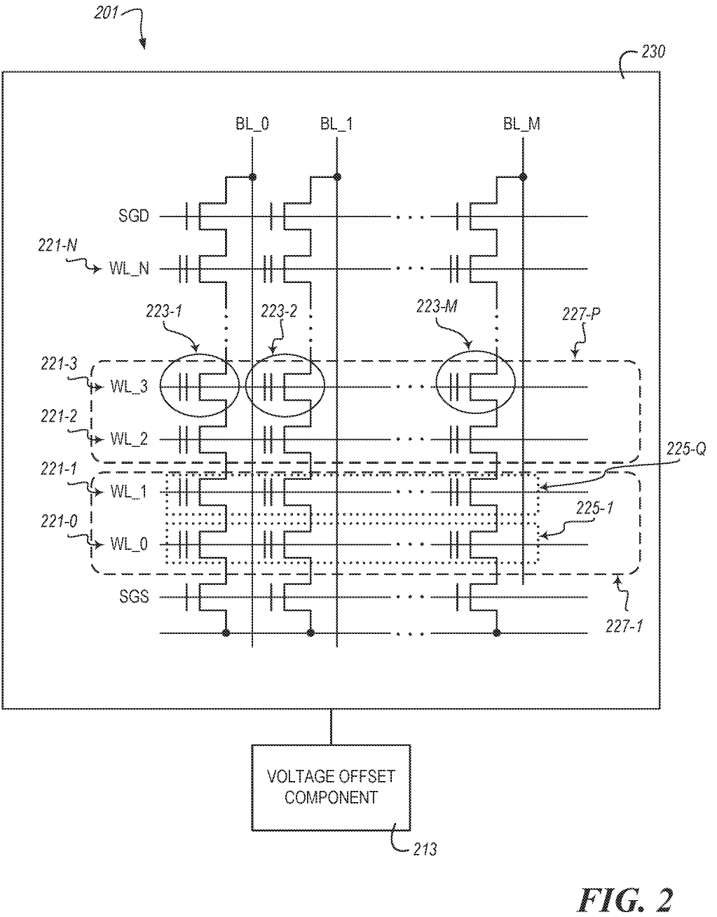

FIG. 2 illustrates an example of a memory device 230 coupled to a voltage offset component 213 in accordance with some embodiments of the present disclosure. The memory device 230 can be analogous to the memory device 130 illustrated in FIG. 1, herein, while the voltage offset component 213 can be analogous to the voltage offset component 113 illustrated in FIG. 1, herein. The memory device 230 and the voltage offset component 213 can be included in a computing system 201. As shown in FIG. 2, the memory device 230 includes a plurality of bit lines BL_0, BL_1 to BL_M, a plurality of word lines WL_0 221-0, WL_1 221-2, WL_2 221-2, WL_3 221-3, and WL_N 221-N (referred to for brevity as word lines 221-1 to 221-N), one or more select gate drain components SGD, and one or more select gate source components SGS. The bit lines BL_0, BL_1 to BL_M and the word lines WL_0 221-0 to WL_N 221-N are coupled to a plurality of memory cells 223-1, 223-2 to 223-M (referred to for brevity as “the memory cells 233-1 to 233-M” or simply as “the memory cells 223”). A set of the memory cells that are coupled to a particular word line (e.g., the word line WL_1) can comprise a page 225 of memory cells 223-1 to 223-M. One or more pages 225-1 to 225-Q of memory cells 223-1 to 223-M can comprise a word line group 227-1 to 227-P.

Although the memory cells 223-1 to 223-M are not explicitly shown within one of the pages 225-1 to 225-Q, it will be appreciated that memory cells analogous to the memory cells 223-1 to 223-M are repeated throughout the memory device 230 to form an array of such memory cells. In some embodiments, the memory cells are TLCs and can therefore store 3 bits per cell -one bit in a “lower page,” one bit in an “upper page,” and one bit in an “extra page.” Further, a word line group 227 can consist of one or more word lines, which can include multiple memory cells 223. although the pages 225-1 to 225-Q of memory cells are illustrated in a single word line group 227-0, embodiments are not so limited and greater or fewer than the two explicitly illustrated pages of memory 225-1 to 225-Q can be part of the word line group 227-0. In addition, although the word line group 227-P is not shown as including pages of memory cells 223-1 to 223-M, one of ordinary skill in the art will appreciate that the word line group 227-P would contain at least one page of memory cells 223-1 to 223-M.

The voltage offset component 213 can include various circuitry (e.g., one or more processors, controllers, logic circuits, etc.) to perform the operations described herein. The voltage offset component 213 can be provided in the form of an application-specific integrated circuit (ASIC) and/or field programmable gate array (FPGA). In some embodiments, the voltage offset component 213 can include an instruction set architecture (ISA) such as a reduced instruction set architecture (RISC). In embodiments in which the voltage offset component 213 includes a RISC device, the RISC device can include a processing resource that can employ a reduced instruction set architecture (ISA) such as a RISC-V ISA, however, embodiments are not limited to RISC-V ISAs and other processing devices and/or ISAs can be used.

In some embodiments, the voltage offset component 213 can dynamically alter and control application of voltage offset (e.g., read retry offset) signals to particular word line groups 227-1 to 227-P of the memory device 230. As mentioned above, such dynamic alteration and application of the voltage offset signals can occur in response to information collected and/or processed by the voltage offset component 213. Further, such dynamic alteration and application of the voltage offset signals can be controlled by the voltage offset component 213 on a word line group by word line group basis such that a different offset voltage is applied to one or more word line groups 227-1 to 227-P.

As mentioned above, the offset voltage applied to the word line groups 227-1 to 227-P and, hence, to the page 225-1 to 225-Q of memory cells 223-1 to 223-M of the memory device 230, can be based on one or more parameters that correspond to various reliability metrics corresponding to the word line groups 227-1 to 227-P that can impact the RBER of the memory cells 223-1 to 223-M of the memory device 230 and/or the trigger rate of the memory cells 223-1 to 223-M of the memory device 230. The one or more parameters can represent discrete values or contiguous ranges on a spectrum that encompasses varying degrees of stratification of the reliability metrics and/or quality characteristics described herein. A “parameter” or “one or more parameters” can generally refer to discrete values or contiguous ranges of values that can represent aggregated or representative information that corresponds to the reliability metrics and/or quality characteristics described herein. For example, if the reliability metrics and/or quality characteristics include multiple differing reliability metrics and/or quality characteristics, a parameter can refer to a discrete value or a contiguous ranges of values that can represent the multiple differing reliability metrics and/or quality characteristics. In some embodiments, the reliability metrics can include cross-temperature metrics in which a memory cell 223 is read at a different temperature than the memory cell 223 was programmed. Further non-limiting examples of reliability metrics can include read disturb effects experienced by the memory cells 223, a quantity of program-erase cycles experienced by the memory cells 223, and/or data retention characteristics of the memory cells 223, among others.

In some embodiments, the voltage offset component 213 can be configured to monitor the parameters that correspond to these and other reliability metrics to determine a particular voltage offset signal to apply to at least one of the word line groups 227-1 to 227-P. For example, if the voltage offset component 213 determines that the parameters corresponding to one or more of the reliability characteristics for a particular word line group (e.g., the word line group 227-1) are “worse” (e.g., are lower than) than the reliability characteristics for a different word line group (e.g., the word line group 227-P), the voltage offset component 213 can be configured to apply a voltage offset signal that has a greater magnitude (e.g., a higher voltage) than is applied to the word line group 227-P, and vice versa. Embodiments are not so limited, however, and in some embodiments, the voltage offset component 213 can alter a frequency at which an offset voltage signal is applied to the word line groups 227-1 to 227-P. In such embodiments, if the voltage offset component 213 determines that the parameters corresponding to one or more of the reliability characteristics for a particular word line group (e.g., the word line group 227-1) are worse than the reliability characteristics for a different word line group (e.g., the word line group 227-P), the voltage offset component 213 can be configured to apply a voltage offset signal more frequently to the word line group 227-1 than a voltage offset signal is applied to the word line group 227-P, and vice versa.

In some embodiments, the voltage offset component 213 can dynamically alter and control application of the voltage offset (e.g., read retry offset) signals to particular word line groups 227-1 to 227-P of the memory device 230 based on error handling operations performed by the memory device 230. For example, a range of acceptable values, i.e., a range of voltage offset signal values that can be applied to correct drift effects experienced by the memory cells 223 and/or to otherwise ensure the data written to the memory cells 223 is accurately read from the memory cells 223, of a voltage offset signal (e.g., a read retry signal) may change at each stage of an error handling operation (e.g., a NAND error recovery flow) due to operations that are performed at each stage of the error handling operation.

In contrast to approaches that apply a first voltage offset to all word line groups at a first error handling stage, a second voltage offset to all word line groups at a second error handling stage, a third voltage offset to all word line groups at a third error handling stage, a fourth voltage offset to all word line groups at a fourth error handling stage, etc., embodiments herein allow for different voltage offsets to be applied to different word line groups at different error handling stages. For example, embodiments herein allow for the voltage offset component 213 to apply a first voltage offset to a first word line group at a first error handling stage, a second voltage offset to a second word line group at the first error handling stage, a third voltage offset to a third word line group at the first error handling stage, and/or a fourth voltage offset to a fourth word line group at the first error handling stage, etc. Similarly, embodiments herein allow for the voltage offset component 213 to apply a first voltage offset to a first word line group at a first error handling stage, a second voltage offset to the first word line group at a second error handling stage, a third voltage offset to the first word line group at a third error handling stage, and/or a fourth voltage offset to the first word line group at a fourth error handling stage, etc. It will, however, be appreciated that embodiments are not limited to these specific enumerated examples and application of differing voltage offsets to one or more different word line groups at one or more different error handling stages are contemplated within the scope of the disclosure.

In a non-limiting example, an apparatus (e.g., the computing system 201) can include a plurality of pages 225-1 to 225-Q of memory cells 223-1 to 223-M of respective word line groups (e.g., the word line group 227) and a processor (e.g., the voltage offset component 213) coupled to each of the plurality of pages 225-1 to 225-Q of memory cells 223-1 to 223-M. The processor can determine, for a page (e.g., the page 225-1) of memory cells 223-1 to 223-M of a particular word line group 227-1 to 227-P, a parameter corresponding to a quality of the page 225-1 of memory cells 223-1 to 223-M of the particular word line group 227-1 to 227-P. In some embodiments, the processor can be configured to determine a raw bit error rate, a trigger rate, a program-erase count (e.g., a quantity of program-erase cycles experienced by the memory cells 223-1 to 223-M), and/or process variation characteristics of the page 225-1 of memory cells 223-1 to 223-M and/or of the word line groups 227-1 to 227-P for the page 225-1 of memory cells 223-1 to 223-P to determine the parameter corresponding to the quality of the page 225-1 of memory cells 223-1 to 223-P of the particular word line group 227-1 to 227-P.

The processor can determine, for the page 225-1 of memory cells 223-1 to 223-M, a read recovery offset voltage based, at least in part, on the parameter corresponding to the quality of the page 225-1 of memory cells 223-1 to 223-M and control application of a signal applied to the particular word line group 227-1 to 227-P. In some embodiments, the read recovery offset voltage signal can be applied to one or more pages 225-1 in a same word line group (e.g., the particular word line groups 227-1 to 227-P). The signal can correspond to the determined read recovery offset voltage and/or the signal can be applied to correct a voltage shift experienced by the page 225-1 of memory cells 223-1 to 223-M of the particular word line group 227-1 to 227-P. Embodiments are not so limited, however, and in some embodiments, the processor can determine an age of the plurality of pages 225-1 to 225-Q of memory cells 223-1 to 223-M to determine the read recovery offset voltage and/or the processor can determine a quantity of program-erase cycles experienced by the memory cells 223-1 to 223-M to determine the read recovery offset voltage.

As described in more detail herein, the processor can be configured to control application of the signal applied to the particular word line group 227-1 to 227-P such that a voltage corresponding to the signal is different that a voltage of a signal applied to a different word line group. For example, if the particular word line group is the word line group 227-1, the processor can be configured to control application of the signal applied to the particular word line group 227-1 such that a voltage corresponding to the signal is different than a voltage of a signal applied to the word line group 227-P.

In some embodiments, the processor can be configured to determine the read recovery offset voltage to be applied to the particular word line group 227-1 to 227-P based, at least in part, on a determined error handling stage performed using the page 225-1 of memory cells 223-1 to 223-M of the particular word line group 227-1 to 227-P, as described above.

The apparatus can further include a data structure (e.g., the data structure 118 illustrated in FIG. 1, herein) that includes voltage offset information corresponding to respective word line groups 227-1 to 227-P to which the plurality of pages 225-1 to 225-Q of memory cells 223-1 to 223-M are associated. In some embodiments, the data structure can include voltage offset information corresponding to the respective word line groups 227-1 to 227-P based on a current error handling stage, as described above. The data structure can be accessible by the processor such that the processor can access the data structure to determine the read recovery offset voltage to be used in performance of an operation related to application of a voltage offset to a word line group.

In some embodiments, the processor can determine the parameter, determine the read recovery offset voltage, and control application of the signal during runtime of a computing device (e.g., the computing system 100 illustrated in FIG. 1) in which the processor and the plurality of pages 225-1 to 225-Q of memory cells 223-1 to 223-M are deployed. That is, in some embodiments, the voltage offset component 213 is configured to perform operations related to application of a voltage offset to a word line group dynamically as the memory device 230 operates “in the field.”

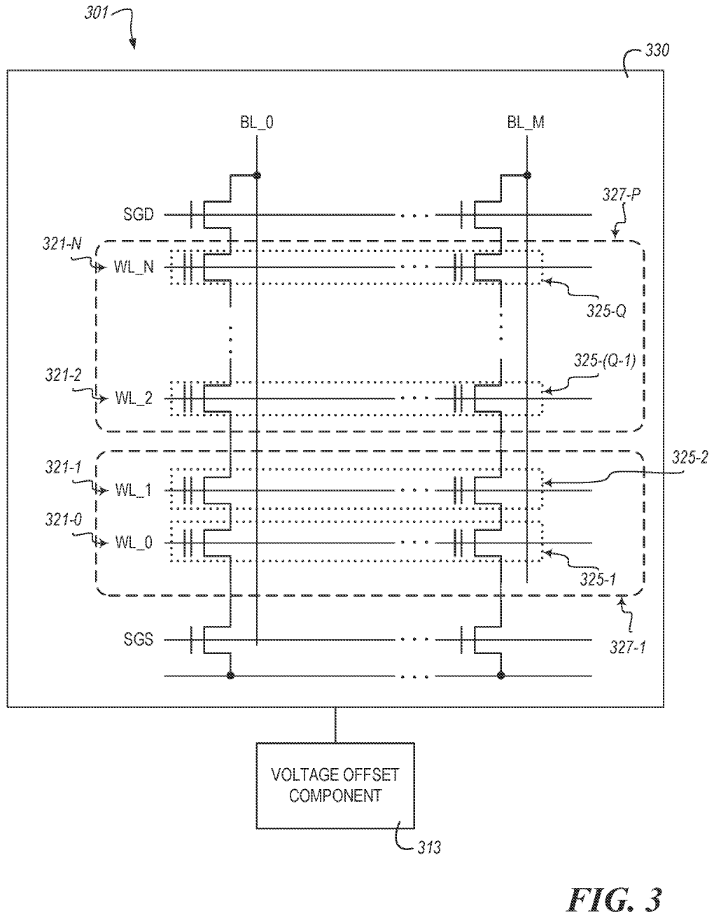

FIG. 3 illustrates another example of a memory device 330 coupled to a voltage offset component 313 in accordance with some embodiments of the present disclosure. The memory device 330 can be analogous to the memory device 130/230 illustrated in FIG. 1 and FIG. 2, herein, while the voltage offset component 313 can be analogous to the voltage offset component 113/213 illustrated in FIG. 1 and FIG. 2, herein. As illustrated in FIG. 3, the memory device 330 includes strings of memory cells coupled to bit lines BL_0 to BL_M and to word lines WL_0 321-0, WL_1 321-1, WL_2 321-2 to WL_N 321-N. Memory cells (e.g., the memory cells 223 illustrated in FIG. 2, herein) of the word lines 321-0 to 321-N can comprise pages 325-1, 325-2, 325-(Q-1), to 325-Q of memory cells. As describe above, such pages 325-1 to 325-Q of memory cells can be part of at least one word line group 327-1 to 327-P.

As shown in FIG. 3, one or more pages (e.g., the pages 325-1 and 325-2) of memory cells can be associated with a particular word line group (e.g., the word line group 327-1) and one or more different pages (e.g., the pages 325-(Q-1) and 325-Q) of memory cells can be associated with a different word line group (e.g., the word line group 327-P). So as not obfuscate the illustrations of the disclosure, FIG. 3 illustrates two pages of memory cells that comprise a particular word line group and two different pages of memory cells that comprise a different word line group; However, it is contemplated that any of the word line groups of the memory device(s) disclosed herein may contain greater than or fewer than the explicitly illustrated number of pages of memory cells shown in FIG. 3.

As described above in connection with FIG. 2, the voltage offset component 313 can dynamically alter and control application of voltage offset (e.g., read retry offset) signals to particular word line groups 327-1 to 327-P of the memory device 330. In some embodiments, this dynamic alteration and control of the application of voltage offset (e.g., read retry offset) signals to the particular word line groups 327-1 to 327-P of the memory device 330 can be based on quality parameters that correspond to various reliability metrics corresponding to the word line groups 327-1 to 327-P that can impact the RBER of the pages of memory cells of the memory device 330 and/or the trigger rate of the word line groups 327-1 to 327-P of the memory cells of the memory device 330.

In a non-limiting example, a system (e.g., the computing system 100 illustrated in FIG. 1 and/or the computing system 201) includes a first word line group (e.g., the word line group 327-1) comprising a first page of memory cells (e.g., the page of memory cells 325-1) and a second word line group (e.g., the word line group 327-P) comprising a second page of memory cells (e.g., the page of memory cells 325-(Q-1)). In some embodiments, the first word line group can include multiple pages of memory cells (e.g., the page of memory cells 325-1 and the page of memory cells 325-2) and the second word line group can include multiple pages of memory cells (e.g., the page of memory cells 325-(Q-1) and the page of memory cells 325-Q).

Continuing with this non-limiting example, the system can include a controller (e.g., the voltage offset component 313) that is configured to determine a first parameter corresponding to a quality of the first page of memory cells of the first word line group and determine a second parameter corresponding to a quality of the second page of memory cells of the second word line group. The controller can determine a first voltage offset (e.g., a first read retry offset signal) to be applied to the first set of memory cells of the first word line group based on the first parameter and/or determine a second voltage offset (e.g., a second read retry offset signal) to be applied to the second set of memory cells of the second word line group based on the second parameter. As described herein, the first voltage offset can have a different magnitude (e.g., can have a different voltage associated therewith) than the second voltage offset.

The controller can further control application of first signaling corresponding to the first voltage offset to the first word line group and control application of second signaling corresponding to the second voltage offset to the second word line group. In some embodiments, the controller can be configured to control application of the first signaling and the second signaling such that the first offset voltage is applied to the first word line group independently of application of the second offset voltage to the second word line group. As described above, the controller can be configured to control application of the first signaling and the second signaling during runtime of a memory device in which the controller, the first word line group, and the second word line group are deployed.

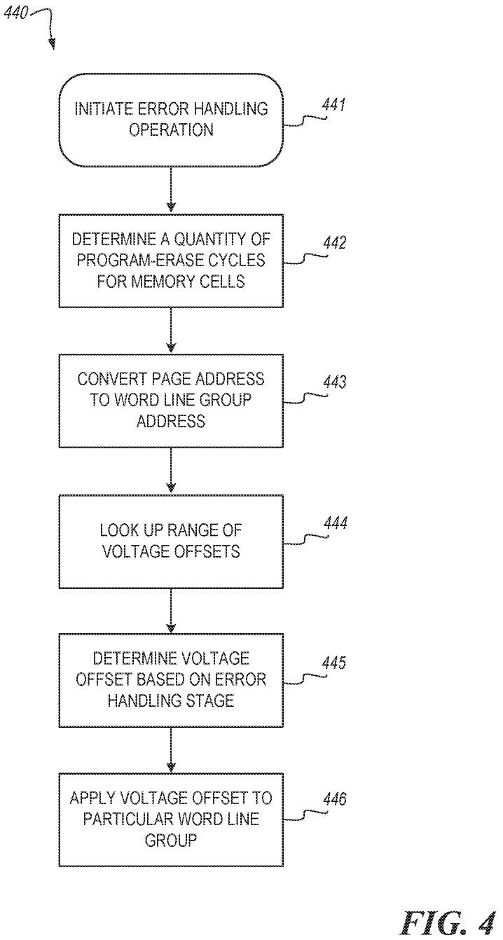

The controller can be configured to determine the first voltage offset based, at least in part, on a determined error handling stage performed using the first page of memory cells and/or determine the second voltage offset based, at least in part, on a determined error handling stage performed using the second page of memory cells. For example, the controller can determine the first voltage offset and/or the second voltage offset based on stages of an error handling operation described in connection with FIG. 1 and FIG. 4, herein.

Continuing with this non-limiting example, the system can include a data structure (e.g., the data structure 118 illustrated in FIG. 1, herein) that includes voltage offset information corresponding to the first word line group and the second word line group. As described herein, the data structure can be accessible by the controller and the controller can configured to access the data structure to determine a read recovery offset voltage range for the first word line group to determine the first voltage offset and access the data structure to determine a read recovery offset voltage range for the second word line group to determine the second voltage offset.

FIG. 4 illustrates an example flow diagram 440 corresponding to application of a voltage offset to a word line group in accordance with some embodiments of the present disclosure. At operation 441, an error handling operation can be initiated. In some embodiments, the error handling operation can be initiated to perform error handling for a NAND memory device (e.g., the memory device 130/230/330 illustrated in FIG. 1, FIG. 2, and FIG. 3, herein). As will be appreciated, an error handling operation can generally be performed to recover data read from a memory device by attempting to correct errors in data stored by the memory device that may have been introduced as a result of inherent characteristics of the memory device, such as process variations, etc., as well as errors that can be introduced due to temperatures, workloads, and/or program-erase cycles, among other factors the memory device experiences during operation.

An error handling operation can be performed in multiple stages that each seek to recover data read from a memory device by attempting to correct errors in data stored by the memory device. In general, each successive stage of an error handling operation can incur additional latency in data retrieval from the memory device, thereby decreasing performance of the memory device and reducing the QoS of the memory device. In order to reduce a quantity of stages of an error handling operation, and therefore to improve the performance of the memory device, a processor or controller (e.g., the voltage offset component 113/213 illustrated in FIG. 1, FIG. 2, and FIG. 3, herein) can apply voltage offsets to particular word line groups of a memory device, as described herein.

At operation 442, a quantity of program-erase cycles that have been undergone by memory cells (e.g., the memory cells 223-1 to 223-M illustrated in FIG. 2, herein) of the memory device can be determined. In some embodiments, the processor or controller can determine the quantity of program-erase cycles undergone by the memory cells. In some embodiments, the quantity of program-erase cycles can be determined for one or more pages (e.g., the pages 225-1 to 225-Q illustrated in FIG. 2, herein) of memory cells and/or one or more word line groups (e.g., the word line groups 227-1 to 227-P illustrated in FIG. 2, herein).

At operation 443, a page address can be converted to a word line address. For example, page addresses may be accessed by a corresponding logical address, while a word line address can correspond to a physical address in the memory device. In some embodiments, as shown at operation 443, logical page addresses corresponding to one or more of the pages of memory cells can be converted to physical addresses that correspond to one or more of the word line groups that are coupled to the pages of memory cells. Operation 443 can be performed by a processor or controller, such as the voltage offset component described herein.

At operation 444, a range of voltage offsets can be looked up (e.g., accessed). For example, an operation to access a look up table that includes ranges of voltage offsets for the word line groups of the memory device can be performed. In some embodiments, the look up table can be stored by the data structure 118 illustrated in FIG. 1 and described in more detail above in connection with FIG. 2. In some embodiments, the range of voltage offsets can be specified for particular word line groups and/or can be based on an error handling stage being performed by the memory device. At operation 445, a voltage offset to be applied to a particular word line group (or set/page of memory cells) can determined based on the error handling stage being performed by the memory device, as described above. For example, if there are eight (8) error handling stages for four (4) positive offsets and four (4) negative offsets, the offset can be determined as shown in Equation 1, below. Further, in some embodiments, operation 444 and/or operation 445 can be performed by a processor or controller, such as the voltage offset component described herein.

$$O F F S E T = \left(\frac{E r r o r H a n d l i n g S t a g e}{8}\right) ∗ \left[M a x P E C - M i n P E C\right]$$

Embodiments are not so limited, however, and in some embodiments, the offset of Equation 1 can be modified based on any quality characteristic of the memory cells (e.g., read disturb metrics, cross-temperature metrics, and/or DR metrics, among others). As mentioned above, the offset(s) (e.g., read recovery offset(s)) can be applied to individual word line groups and can track and/or match a maximum and minimum value ascribed to such quality characteristics for each individual word line group.

At operation 446, a voltage offset can be applied to applied to a particular word line group (or set/page of memory cells). The voltage offset applied to the particular word line group can be based on the error handling stage being performed by the memory device, as described above. As described herein, the voltage offset applied to the particular word line group can be different than a voltage offset applied to at least one different word line group of the memory device. In some embodiments, operation 446 can be performed by a processor or controller, such as the voltage offset component described herein.

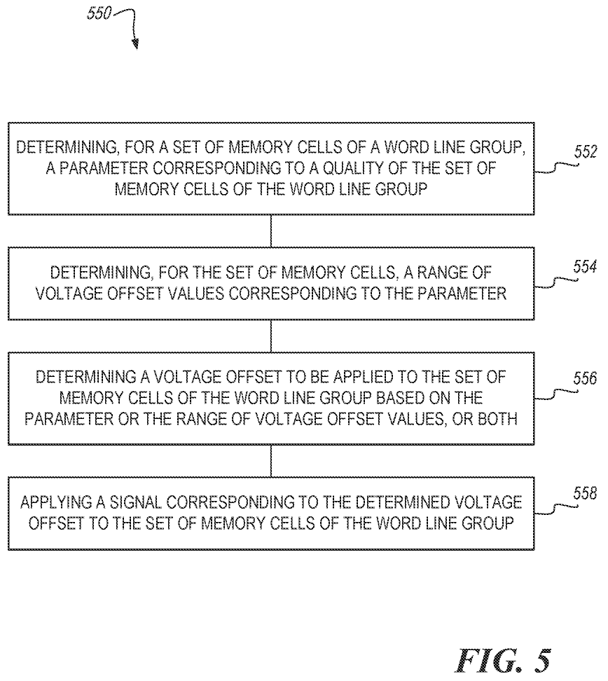

FIG. 5 is a flow diagram corresponding to a method 550 for application of a voltage offset to a word line group in accordance with some embodiments of the present disclosure. The method 550 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 550 is performed by the voltage offset component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 552, the method 550 includes determining, for a set of memory cells (e.g., one or more pages of memory cells 225/325 illustrated in FIG. 2 and FIG. 3, herein) of a word line group (e.g., one or more of the word line groups 227/327 illustrated in FIG. 2 and FIG. 3, herein), a parameter corresponding to a quality of the set of memory cells of the word line group. In some embodiments, the method 550 can include determining a raw bit error rate, a trigger rate, or a program-erase count, or any combination thereof for the set of memory cells as part of determining the parameter corresponding to the quality of the set of memory cells of the word line group.

At operation 554, the method 550 includes determining, for the set of memory cells, a range of voltage offset values corresponding to the parameter. In some embodiments, the method 550 can include determining the voltage offset to be applied to the set of memory cells of the word line group based, at least in part, on a determined error handling stage performed using the set of memory cells.

At operation 556, the method 550 includes determining a voltage offset to be applied to the set of memory cells of the word line group based on the parameter and/or the range of voltage offset values. In some embodiments, the method 550 can include determining the voltage offset to be applied to the set of memory cells of the word line group by accessing a data structure (e.g., the data structure 118 illustrated in FIG. 1, herein) that includes voltage offset information corresponding to the word line group.

At operation 558, the method 550 includes applying a signal corresponding to the determined voltage offset to the set of memory cells of the word line group. In some embodiments, the method 550 can further include applying, to a different set of memory cells of a different word line group, a different signal corresponding to a determined voltage offset for the different set of memory cells of the different word line group.

The method 550 can further include determining a read recovery offset voltage to be applied to the set of memory cells of the word line group as part of determining the voltage offset to be applied to the word line group associated with the set of memory cells. In some embodiments, the method 550 can further include determining the parameter, determining the range of values, determining the voltage offset, and applying the signal during runtime of a memory device in which the set of memory cells of the word line group is deployed. As will be appreciated, “runtime” of a memory device generally refers to a condition in which the memory device is actively connected to a host system (e.g., the host system 120 illustrated in FIG. 1, herein) such that memory device is receiving commands from the host system and executing the commands from the host system.

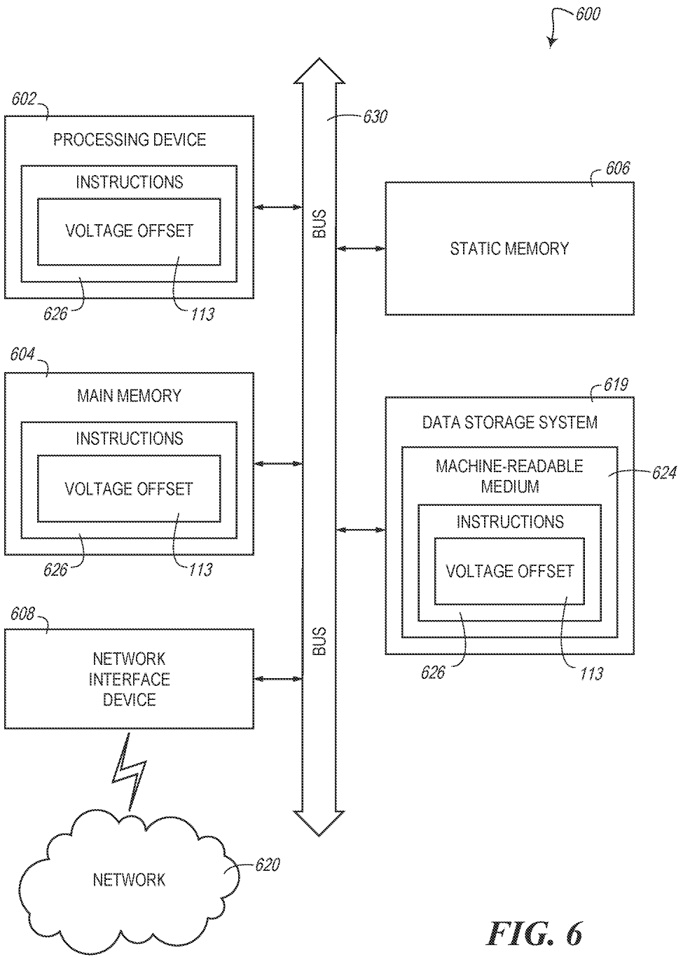

FIG. 6 is a block diagram of an example computer system 600 in which embodiments of the present disclosure may operate. For example, FIG. 6 illustrates an example machine of a computer system 600 within which a set of instructions, for causing the machine to perform any one or more of the methodologies discussed herein, can be executed. In some embodiments, the computer system 600 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the voltage offset component 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a data storage system 619, which communicate with each other via a bus 630.

The processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 602 can also be one or more special-purpose processing devices such as an application specific integrated circuit (ASIC), a field programmable gate array (FPGA), a digital signal processor (DSP), network processor, or the like. The processing device 602 is configured to execute instructions 626 for performing the operations and steps discussed herein. The computer system 600 can further include a network interface device 908 to communicate over the network 620.

The data storage system 619 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIG. 1.

In some embodiments, the instructions 626 include instructions to implement functionality corresponding to a voltage offset component (e.g., the voltage offset component 113 of FIG. 1). While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system’s registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method, comprising:
determining, for a set of memory cells of a word line group, a parameter corresponding to a quality of the set of memory cells of the word line group;
determining, for the set of memory cells, a range of voltage offset values corresponding to the parameter;
determining a voltage offset to be applied to the set of memory cells of the word line group based on the parameter or the range of voltage offset values, or both; and
applying a signal corresponding to the determined voltage offset to the set of memory cells of the word line group.

2. The method of claim 1, further comprising determining a read recovery offset voltage to be applied to the set of memory cells of the word line group as part of determining the voltage offset to be applied to the word line group associated with the set of memory cells.

3. The method of claim 1, further comprising determining a raw bit error rate, a trigger rate, or a program-erase count, or any combination thereof for the set of memory cells as part of determining the parameter corresponding to the quality of the set of memory cells of the word line group.

4. The method of claim 1, further comprising applying, to a different set of memory cells of a different word line group, a different signal corresponding to a determined voltage offset for the different set of memory cells of the different word line group.

5. The method of claim 1, further comprising determining the parameter, determining the range of values, determining the voltage offset, and applying the signal during runtime of a memory device in which the set of memory cells of the word line group is deployed.

6. The method of claim 1, further comprising determining the voltage offset to be applied to the set of memory cells of the word line group by accessing a data structure that includes voltage offset information corresponding to the word line group.

7. The method of claim 1, further comprising determining the voltage offset to be applied to the set of memory cells of the word line group based, at least in part, on a determined error handling stage performed using the set of memory cells.

8. An apparatus, comprising:
a plurality of pages of memory cells of respective word line groups; and
a processor coupled to each of the plurality of pages of memory cells, wherein the processor is configured to:
determine, for a page of memory cells of a particular word line group, a parameter corresponding to a quality of the page of memory cells of the particular word line group;
determine, for the page of memory cells, a read recovery offset voltage based, at least in part, on the parameter corresponding to the quality of the page of memory cells; and
control application of a signal applied to the particular word line group, wherein the signal:
corresponds to the determined read recovery offset voltage, and
is applied to correct a voltage shift experienced by the page of memory cells of the particular word line group.

9. The apparatus of claim 8, wherein the processor is configured to control application of the signal applied to the particular word line group such that a voltage corresponding to the signal is different than a voltage of a signal applied to a different word line group.

10. The apparatus of claim 8, wherein the processor is further configured to determine the read recovery offset voltage to be applied to the particular word line group based, at least in part, on a determined error handling stage performed using the page of memory cells of the particular word line group.

11. The apparatus of claim 8, wherein the processor is further configured to determine a raw bit error rate, a trigger rate, a program-erase count, or process variation characteristics of the page of memory cells, or any combination thereof, for the page of memory cells to determine the parameter corresponding to the quality of the page of memory cells of the particular word line group.

12. The apparatus of claim 8, wherein the processor is further configured to determine the parameter, determine the read recovery offset voltage, and control application of the signal during runtime of a computing device in which the processor and the plurality of pages of memory cells are deployed.

13. The apparatus of claim 8, further comprising a data structure that includes voltage offset information corresponding to respective word line groups to which the plurality of pages of memory cells are associated and that is accessible by the processor, wherein the processor is further configured to access the data structure to determine the read recovery offset voltage.

14. The apparatus of claim 8, wherein the processor is further configured to determine an age of the plurality of pages of memory cells to determine the read recovery offset voltage.

15. A system, comprising:
a first word line group comprising a first page of memory cells;
a second word line group comprising a second page of memory cells; and
a controller coupled to the first word line group and the second word line group, wherein the controller is configured to:
determine a first parameter corresponding to a quality of the first page of memory cells of the first word line group;
determine a second parameter corresponding to a quality of the second page of memory cells of the second word line group;
determine a first voltage offset to be applied to the first set of memory cells of the first word line group based on the first parameter;
determine a second voltage offset to be applied to the second set of memory cells of the second word line group based on the second parameter;
control application of first signaling corresponding to the first voltage offset to the first word line group; and
control application of second signaling corresponding to the second voltage offset to the second word line group.

16. The system of claim 15, wherein the first voltage offset has a different magnitude than the second voltage offset.

17. The system of claim 15, wherein the controller is configured to control application of the first signaling and the second signaling such that the first offset voltage is applied to the first word line group independently of application of the second offset voltage to the second word line group.

18. The system of claim 15, wherein the controller is configured to control application of the first signaling and the second signaling during runtime of a memory device in which the controller, the first word line group, and the second word line group are deployed.

19. The system of claim 15, wherein the controller is further configured to:
determine the first voltage offset based, at least in part, on a determined error handling stage performed using the first page of memory cells; and
determine the second voltage offset based, at least in part, on a determined error handling stage performed using the second page of memory cells.

20. The system of claim 15, further comprising a data structure that includes voltage offset information corresponding to the first word line group and the second word line group, wherein the data structure is accessible by the controller, and wherein the controller is further configured to:
access the data structure to determine a read recovery offset voltage range for the first word line group to determine the first voltage offset; and
access the data structure to determine a read recovery offset voltage range for the second word1 line group to determine the second voltage offset.
